(19) United States
(12) Patent Application Publication
(10) Pub. No.: US 2024/0389372 A1
(43) Pub. Date: Nov. 21, 2024

(54) ELECTRICALLY CONDUCTIVE COATING OF AN ELECTRICAL COMPONENT FOR ELECTRICALLY CONDUCTIVELY CONTACTING A BUS BAR LOCATED OUTSIDE THE COATING

(71) Applicant: Heliatek GmbH, Dresden (DE)

(72) Inventor: Dustin Fischer, Dresden (DE)

(21) Appl. No.: 18/704,069

(22) PCT Filed: Oct. 25, 2022
(86) PCT No.: PCT/DE2022/100789

§ 371 Date: Apr. 24, 2024

(30) Foreign Application Priority Data
Oct. 25, 2021 (DE) 10 2021 127 720.5

(51) Int. Cl. H10K 30/88; H10K 30/89

(52) U.S. Cl. CPC H10K 30/88; H10K 30/89

(57) ABSTRACT

The invention relates to an electrically conductive coating (100) of an electrical component (200) for electrically conductively contacting a first busbar (300) located outside the coating (100), to a use of such an electrically conductive coating (100), to an electrical component (200) having such an electrically conductive coating (100), and to a method for coating an electrical component (200) with such an electrically conductive coating (100).

The invention relates to an electrically conductive coating of an electrical component for electrically conductively contacting a busbar arranged outside the coating, to a use of such an electrically conductive coating, to an electrical component having such an electrically conductive coating, and to a method for coating an electrical component with such an electrically conductive coating.

The electrical component is in particular a photovoltaic element, for example a CIS, CIGS, GaAs, or Si element, a perovskite element, or an organic photovoltaic element. Organic photovoltaic elements comprise a layer system composed of a sequence of thin layers with a front electrode, a back electrode and with at least one organic photoactive layer between the front electrode and the back electrode, which are preferably vapor-deposited in vacuo or processed from solution. The fundamental construction of organic photoactive components is described for example in WO 2004 083 958 or WO 2011 138 021, wherein the organic photoactive layer can comprise polymers or small molecules. While polymers are distinguished by their not being evaporable and therefore only being able to be applied from solutions, small molecules are usually evaporable and can be applied either from solution or by evaporation in vacuo. The electrical link may be implemented by metal layers, transparent conductive oxides and/or transparent conductive polymers.

Organic photovoltaic elements exhibit a greatly reduced lifetime after direct contact with air, in particular oxygen, and/or moisture, in particular water. The layer system must therefore be protected from air and moisture, since otherwise the organic layer may be damaged. Therefore, a protective layer is required for protecting the electrical component.

The prior art discloses protective layers for producing organic electrical components. DE102015116418A1 discloses a protective layer and a method for applying the protective layer in the context of a continuous roll-to-roll method for producing a semifinished product of organic electrical components, comprising a layer stack on a substrate film, wherein the protective layer protects the layer stack from environmental influences and damage caused by handling before and during final production.

What is disadvantageous about the prior art, however, is that in the case of an electrical component, in particular a photovoltaic element, encapsulated or provided with a protective layer, the protective layer has to be opened in order to pass the electrical current into or out of the electrical component, from an electrode to a busbar arranged outside the protective layer or the encapsulation. Atmospheric oxygen or moisture can penetrate into the interior of the electrical component through such an opening.

Therefore, the invention is based on the object of providing a coating, in the case of which the aforementioned disadvantages do not occur, which coating forms in particular a protective layer on a layer system of an electrical component and does not have to be opened for contacting electrodes of the layer system with a busbar located outside the coating, which may result in air and/or moisture penetrating into the layer system.

The object is achieved by the subjects of the independent claims. Advantageous configurations are evident from the dependent claims.

The object is achieved, in particular, by providing an electrically conductive coating of an electrical component for electrically conductively contacting a first busbar arranged outside the coating, the electrical component having at least one cell with at least one structured layer system, wherein the at least one layer system has a front electrode, a back electrode, and at least one photoactive layer, and the at least one photoactive layer is arranged between the front electrode and the back electrode, wherein the at least one layer system is structured in such a way that the back electrode is interrupted by at least one trench, and at least the back electrode of the at least one cell is coated with the coating and the at least one trench of the back electrode is filled with the coating. In this case, the coating has a resistivity (specific electrical resistance) of 0.01 to 10,000 Ωm, wherein a ratio of the electrical resistance between the back electrode and the first busbar of the coating (R_{layer}) and the electrical resistance over the width of the trench with the coating (R_{trench}) is at least 1:1000.

According to the invention, the electrical resistance over the width of the at least one trench—interrupting the back electrode—with the coating (R_{trench}) is greater than the electrical resistance of the coating between the back electrode and the first busbar (R_{layer}). According to the invention, the electrical current does not flow through the trench filled with the coating, since the electrical resistance, in particular the electrical resistance resulting from the geometric dimensions, over the width of the trench is too great. An electrical current flow between the back electrode and the busbar is fostered as a result. The invention preferably relates to a protective layer, more particularly winding protection, for protecting the electrical component and for electrically conductively contacting a busbar arranged outside the coating.

A coating is understood to mean in particular a layer which forms protection, in particular a barrier, against chemical compounds, contaminants, moisture and/or oxygen, in particular atmospheric oxygen. A protective layer is also understood to mean in particular a layer for increasing the mechanical durability, in particular scratch resistance, and/or a filter layer, preferably a layer with a UV filter.

An electrical component is understood to mean in particular a photovoltaic element. The photovoltaic element is preferably constructed from a plurality of cells, which can be interconnected in series or in parallel. The plurality of cells can be arranged and/or interconnected in various ways in the electrical component. The electrical component can be a semifinished product or a finished product. In one preferred embodiment, an electrical component is understood to mean a semifinished product of an electrical component.

A front side of an electrical component, in particular of a photovoltaic element, is understood to mean a side of the electrical component that faces sunlight as intended. Accordingly, a back side of an electrical component, in particular of a photovoltaic element, is understood to mean a side of the electrical component that faces away from sunlight as intended.

A busbar is understood to mean in particular an arrangement which is electrically conductively connected for the purpose of electrical contacting as a central distributor of electrical energy to incoming and outgoing lines, preferably connected to at least one front electrode and/or at least one back electrode of the photovoltaic element. The busbar is embodied in particular in planar fashion as a band, strip, or plate.

A busbar arranged outside the coating is understood to mean in particular a busbar arranged on the coating on a side of the layer system opposite to the layer system, in particular a busbar arranged directly on the coating.

The electrically conductive coating protects the electrical component, in particular the layer system of the electrical component, from external influences, wherein the layer system of the electrical component not being damaged, and supplementarily provides an electrically conductive contacting of at least one front electrode and/or back electrode of the at least one cell of the electrical component to at least one busbar arranged outside the coating.

In one preferred embodiment of the invention, the electrical component has a substrate, wherein the layer system is arranged on the substrate.

In one preferred embodiment of the invention, a viscosity of the precursor, of the matrix material and/or of the dopant individually or as a mixture is 0.1 mPas to 2000 mPas, preferably 0.1 mPas to 1000 mPas, preferably 1 mPas to 2000 mPas, preferably 1 mPas to 1000 mPas, preferably 1 mPas to 500 mPas, preferably 10 mPas to 2000 mPas, preferably 10 mPas to 1000 mPas, or preferably 10 mPas to 500 mPas. This ensures in particular that the coating is arranged in a form-fitting and/or integrally bonded manner on the electrical component, in particular the at least one trench is completely filled with the coating.

In one preferred embodiment of the invention, the layer system of the at least one cell is structured, in particular laser-structured, for the purpose of interconnecting individual cells among one another, and for the purpose of electrically isolating individual cells.

Laser structuring of an electrical component, in particular of individual layers of a layer system and/or of a complete layer system, is understood to mean in particular interconnection of individual layers of the layer system and/or cells on an electrical component, or electrical isolation of cells. For the purpose of interconnecting individual cells among one another, in particular a front electrode of a first cell is electrically conductively connected to a back electrode of a second cell. In one preferred embodiment of the invention, there is monolithic interconnection of the electrical component, in particular cells of the electrical component among one another.

A width of the at least one trenches is understood to mean in particular a distance between two opposite parts of the back electrode at an electrically conductive interruption of the back electrode by the at least one trench.

In one preferred embodiment of the invention, a ratio of the width of the trench to the shortest distance between the busbar and the front electrode and/or back electrode is at least 1:10, preferably at least 1:20, preferably at least 1:30, or preferably at least 1:100.

In one preferred embodiment of the invention, a distance between the busbar and the at least one trench is from 100 μm to 100 mm, preferably from 100 μm to 10 mm, preferably from 100 μm to 1 mm, or preferably from 1 mm to 10 mm, relative to the shortest distance between the busbar and the trench.

In one preferred embodiment of the invention, the coating is an electrically conductive winding protection. Winding protection is understood to mean in particular a protective layer for protecting an electrical component from environmental influences and/or damage. After applying the coating as winding protection, this enables an electrical component coated with the coating to be transferred into a further apparatus in which further processing steps are performed.

In one preferred embodiment of the invention, the coating is arranged in a form-fitting and/or integrally bonded manner on the electrical component, in particular the at least one trench is filled with the coating in a form-fitting and/or integrally bonded manner.

In one preferred embodiment of the invention, the at least one cell has a width of 5 mm to 50 mm, preferably of 10 mm to 30 mm.

In one preferred embodiment of the invention, a cell has a length of 5 cm to 20 m, preferably of 50 cm to 20 m, or preferably of 50 cm to 10 m.

In one preferred embodiment of the invention, the coating is at least largely transmissive to light in the visible wavelength range, in particular at least largely transparent.

In one particularly preferred embodiment of the invention, the at least one photoactive layer is formed from organic materials, preferably from small organic molecules or polymeric organic molecules, more particularly preferably from small organic molecules. In one preferred embodiment of the invention, the organic photoactive layer is applied by evaporating small organic molecules.

Small molecules are understood to mean in particular absorber materials which comprise a well-defined number of monomers, typically less than ten, and have a well-defined mass, typically of less than 1500 g/mol, preferably less than 1200 g/mol, and are free of undefined, possibly reactive groups at the end of the molecular chain such as may be present as a byproduct of a polymerization chain reaction in polymers.

The electrically conductive coating according to the invention of an electrical component has advantages in comparison with the prior art. Advantageously, the coating protects the layer system of the electrical component from environmental influences and damage, in particular also before and during final production, and at the same time provides an electrically conductive contacting of the layer system with the at least one busbar of the photovoltaic element. In this case, the specific conductivity of the coating is low enough that the latter does not influence a monolithic interconnection of the electrical component. In this case, the specific conductivity of the coating is high enough that the resistance between electrode and busbar largely does not generate any additional losses. Advantageously, the coating does not have to be subsequently opened for the purpose of electrically contacting the layer system with a busbar arranged outside. Advantageously, the lifetime of an electrical component is increased, since there is no opening in the coating through which moisture can penetrate into the layer system. Advantageously, no further method steps are necessary for electrically conductively contacting with a busbar arranged outside the coating. Advantageously, the method is able to be integrated into a roll-to-roll method for producing an electrical component.

A roll-to-roll method is understood to mean in particular the production of flexible electrical components which are applied to a web composed of flexible plastic or metal films, in particular with continuous method implementation. The roll-to-roll method is characterized for example by a continuous substrate, in particular composed of a plastic film, for example PET or PEN. Materials are applied to this substrate in order to form electrical components, in particular by means of vapor deposition, printing, coating, sputtering or plasma deposition.

In accordance with one development of the invention, it is provided that a ratio of the layer thickness of the coating to the width of the at least one trench is at least 1:10, preferably at least 1:20, preferably at least 1:30, preferably at least 1:100, preferably at least 1:1000, preferably 1:5 to 1:5000, preferably 1:10 to 1:10,000, preferably 1:10 to 1:1000, preferably 1:20 to 1:500, or preferably 1:20 to 1:200.

In accordance with one development of the invention, it is provided that a width of the at least one trench is 1 μm to 1 mm, preferably 10 μm to 1 mm, preferably 50 μm to 1 mm, preferably 1 μm to 400 μm, preferably 10 μm to 400 μm, or preferably 10 μm to 200 μm.

In accordance with one development of the invention, it is provided that a layer thickness of the coating is 100 nm to 100 μm, preferably 500 nm to 10 μm.

In accordance with one development of the invention, it is provided that a ratio of a layer thickness of the back electrode to a width of the first busbar is at least 1:10, preferably at least 1:30, preferably 1:5 to 1:5000, preferably 1:10 to 1:1000, or preferably 1:20 to 1:200.

In accordance with one development of the invention, it is provided that the width of the first busbar is 0.1 cm to 30 cm, preferably 0.1 cm to 20 cm, preferably 0.1 cm to 10 cm, preferably 0.5 cm to 30 cm, preferably 0.5 cm to 20 cm, preferably 0.5 cm to 10 cm, preferably 0.5 cm to 5 cm, or preferably 1 cm to 3 cm.

In accordance with one development of the invention, it is provided that the layer thickness of the back electrode is 10 nm to 1 μm, preferably 10 nm to 500 nm, preferably 20 nm to 500 nm, or preferably 50 nm to 500 nm.

In one preferred embodiment of the invention, a ratio of the width of the trench to the width of the busbar is at least 1:10, preferably at least 1:20, preferably at least 1:30, preferably at least 1:50, preferably at least 1:100, preferably at least 1:200, preferably at least 1:500, or preferably at least 1:1000.

In accordance with one development of the invention, it is provided that the coating has a resistivity of 0.1 to 1000 Ωm, preferably of 1 to 1000 Ωm, preferably of 1 to 500 Ωm, preferably of 1 to 200 Ωm, preferably of 10 to 1000 Ωm, preferably of 10 to 500 Ωm, preferably of 100 to 1000 Ωm, or preferably of 100 to 500 Ωm.

In one preferred embodiment of the invention, the coating has a specific conductivity of 100 to 0.0001 S/m, preferably of 10 to 0.001 S/m.

In accordance with one development of the invention, it is provided that the ratio of the electrical resistance between the back electrode and the first busbar of the coating (R_{layer}) and the electrical resistance over the width of the trench with the coating (R_{trench}) at least 1:100, preferably at least 1:500, preferably at least 1:1000, preferably at least 1:2000, preferably at least 1:5000, or preferably at least 1:10,000, preferably 1:100 to 1:10,0000, preferably 1:1000 to 1:10,0000, or preferably 1:10,000 to 1:10,0000.

In one preferred embodiment of the invention, the layer system is structured in such a way that the at least one photoactive layer is interrupted, and the front electrode and the back electrode of the at least one cell are electrically conductively connected to one another via the interruption of the at least one photoactive layer, wherein the front electrode is electrically conductively isolated from the back electrode by the at least one trench. The front electrode is electrically conductively contacted via a part of the back electrode with a second busbar arranged outside the coating, wherein the electrical resistance from the back electrode over the at least one trench with the coating is greater than the electrical resistance through the coating between the front electrode and the second busbar.

In one preferred embodiment of the invention, the ratio of the electrical resistance between the front electrode and the second busbar of the coating (R_{layer}) and the electrical resistance over the width of the trench with the coating (R_{trench}) is at least 1:100, preferably at least 1:500, preferably at least 1:1000, preferably at least 1:2000, preferably at least 1:5000, or preferably at least 1:10,000, preferably 1:100 to 1:10,0000, preferably 1:1000 to 1:10,0000, or preferably 1:10,000 to 1:10,0000.

In one preferred embodiment of the invention, a width of the second busbar is 0.1 cm to 30 cm, preferably 0.1 cm to 20 cm, preferably 0.1 cm to 10 cm, preferably 0.1 to 5 cm, preferably 0.5 cm to 30 cm, preferably 0.5 cm to 20 cm, preferably 0.5 cm to 10 cm, preferably 0.5 cm to 5 cm, preferably 1 cm to 10 cm, preferably 1 cm to 5 cm, or preferably 1 cm to 2 cm.

In one preferred embodiment of the invention, a ratio of a layer thickness of the back electrode to a width of the second busbar is at least 1:10, preferably at least 1:30, preferably 1:5 to 1:5000, preferably 1:10 to 1:1000, or preferably 1:20 to 1:200.

In one preferred embodiment of the invention, the distance between the first busbar and the second busbar is at least 150% of the width of the at least one trench, preferably at least 200%, preferably at least 300%, preferably at least 500%, or preferably at least 1000%.

In accordance with one development of the invention, it is provided that the at least one layer system is structured in such a way that the structuring has a trench of a first type (P3), which electrically conductively interrupts the back electrode, a trench of a second type (P1), which electrically conductively interrupts the front electrode, and a trench of a third type (P2), which electrically conductively interrupts the at least one photoactive layer, such that the front electrode and the back electrode of the at least one cell are electrically conductively interconnected with one another.

In one preferred embodiment of the invention, a plurality of cells of the photovoltaic element are arranged next to one another and interconnected in series. In this case, each cell has a dedicated electrode and counterelectrode, wherein the series connection is effected by the electrode of one cell being electrically connected to the counterelectrode of the next cell.

In accordance with one development of the invention, it is provided that the coating is formed on a front side of the electrical component and/or on a back side of the electrical component, preferably the coating is formed over the complete extent of the electrical component.

In one preferred embodiment of the invention, the coating is arranged over the entire surface of the electrical component.

In accordance with one development of the invention, it is provided that the coating is formed from:
a) at least one precursor selected from the group consisting of hexamethyldisiloxane (HMDSO), bis-trimethylsilylmethane (BTMSM), tetraethyl orthosilicate (TEOS), hexamethyldisilazane (HMDSN), silane (SiH₄), triethoxysilane (TriEOS), tetramethoxysilane (TMOS), tetramethylsilane (TMS), and trimethoxysilane (TriMOS), bis-diethylamino-silane (BTBAS), preferably using a reaction gas selected from nitrogen or oxygen; or
b) at least one matrix material selected from a), silicon oxycarbides, preferably SiOC or SiOCH, or an SiOCH-like material, preferably silicon carboxynitrides (SiONCH), silicon carbonitrides (SiNCH), silicon nitrides (SiN), silicates (SiO₂), and Al₂O₃; or
c) at least one material selected from b) and at least one dopant, wherein the dopant is selected from the group consisting of diborane, trimethyl boron, and phosphine, or a TCO material, preferably selected from the group consisting of metal alkoxides, metal amides, preferably titanium alkoxide, more preferably titanium tetraisobutoxide, titanium tetraisoethoxide, and titanium tetraisomethoxide, titanium tetra-isopropoxide (TTIP), TiCl₄, dialkyl zinc, preferably dimethyl zinc or diethyl zinc (DEZN), tin chloride, tetramethyltin, tetraethyltin, ITO, In₂O₃, TiO₂, ZnO, and SnO₂.

In one particularly preferred embodiment of the invention, the matrix material of the coating is SiOCH or an SiOCH-like material. SiOCH is a silicon oxide (SiOx) which acquires organic properties by way of a carbon proportion, i.e. the carbon proportion influences the chemical microstructure and the polymer like, partially crosslinked chain structure. The material is more elastic and more flexible than SiOx; it is a nanoporous material having flexible and elastic properties.

In one preferred embodiment of the invention, the coating comprises a carbon proportion of greater than 15 at %, preferably greater than 20 at %, particularly preferably greater than 25 at %.

In one preferred embodiment of the invention, the coating has a proportion of the at least one dopant of 0.1 to 50% by weight, preferably of 0.1 to 20% by weight, preferably of 0.1 to 10% by weight, preferably of 0.5 to 10% by weight, preferably of 1 to 10% by weight, preferably of 1 to 5% by weight, or preferably of 1 to 3% by weight, relative to the total weight of the coating.

In one preferred embodiment of the invention, the coating has flexible properties, wherein an elasticity (modulus of elasticity) of the coating is from 80000 psi to 360000 psi, preferably 10,0000 psi to 300000 psi, preferably 120000 psi to 260000 psi, or preferably 10,0000 psi to 200000 psi.

The object of the present invention is also achieved by providing a use of an electrically conductive coating according to the invention as a protective layer of an electrical component, in particular as winding protection, and for electrically conductively contacting at least one back electrode of a layer system with a first busbar of the electrical component, in particular according to any of the exemplary embodiments described above.

The object of the present invention is also achieved by providing an electrical component having an electrically conductive coating according to the invention, in particular according to any of the exemplary embodiments described above. In this case, in particular the advantages that have already been described in connection with the electrically conductive coating and the use of the electrically conductive coating are afforded for the electrical component. The electrical component has at least one layer system having a front electrode, a back electrode, and at least one photoactive layer, wherein the at least one photoactive layer is arranged between the front electrode and the back electrode, and at least one busbar, wherein the coating is arranged between the at least one layer system and the at least one busbar, such that at least the back electrode is electrically conductively contacted with the at least one busbar, wherein the electrical component is preferably a photovoltaic element.

In one preferred embodiment of the invention, the electrical component is an organic electrical component, preferably an organic photovoltaic element (OPV), an OFET, an OLED or an organic photodetector.

In one preferred embodiment of the invention, the electrical component is a flexible electrical component. A flexible electrical component is understood to mean in particular an electrical component which is bendable and/or stretchable in a certain region. In one preferred embodiment of the invention, the flexible electrical component is a flexible photovoltaic element, in particular a flexible organic photovoltaic element.

In one preferred embodiment of the invention, the electrical component is a semifinished product; accordingly, the electrical component to which the coating is applied is a semifinished product for producing a finally produced electrical component.

A semifinished product is understood to mean in particular a precursor of an electrical component in which at least one further method step is necessary, i.e. further processing is necessary, in order to obtain a finally produced electrical component. Preferably, a semifinished product is understood to mean an electrical component, in particular a photovoltaic cell, which does not yet have a protective layer or does not yet have all protective layers and/or is not yet encapsulated. In contrast, after final production the electrical component is preferably provided and/or encapsulated with all protective layers, in particular equipped with the necessary connections for electrical contacting.

The object of the present invention is also achieved by providing a method for coating an electrical component with an electrically conductive coating according to the invention, in particular according to any of the exemplary embodiments described above. In this case, in particular the advantages that have already been described in connection with the electrically conductive coating, the use of the electrically conductive coating, and the electrical component with the electrically conductive coating are afforded for the method for coating an electrical component. The method comprises the following steps:
a) providing an electrical component having at least one cell with at least one structured layer system, having a front electrode, a back electrode, and at least one photoactive layer arranged between the front electrode and the back electrode, wherein the back electrode is interrupted by at least one trench;
b) applying at least one precursor, one matrix material and/or one dopant simultaneously or as a mixture by means of a deposition method or a printing method at least onto the back electrode and in the at least one trench of the back electrode, such that at least the back electrode is completely covered; and
c) obtaining the coating.

In accordance with one development of the invention, it is provided that after step c) in a step d) at least one first busbar is applied to the coating.

In one preferred embodiment of the invention, the method is carried out in a roll-to-roll method, preferably a continuous roll-to-roll method. In a roll-to-roll method, the substrate in particular is rolled up onto a roll and thereby feeds continuously into a closed apparatus. The layer system is formed there. Preferably, the layer system is produced under a vacuum. If the electrical component is a semifinished product, then the semifinished product can be supplied for further processing.

In one preferred embodiment of the invention, at least one method step of the method, preferably at least step b), is carried out under protective gas, preferably nitrogen or argon.

In one preferred embodiment of the invention, the deposition method is an atomic layer deposition method (ALD), a plasma-enhanced atomic layer deposition method (PEALD), a plasmaless atomic layer deposition method (PLALD), a chemical vapor deposition method (CVD), a plasma-enhanced vapor deposition method (PECVD), a microwave PECVD method, a plasmaless vapor deposition method (PLCVD), or a hollow cathode method.

In one preferred embodiment of the invention, the printing method is a screen printing method, a plotting method, an inkjet printing method, a 3D printing method, a slot die method, a comma bar method, or a blade coating method.

In one preferred embodiment of the invention, the coating pressure is less than 50 Pa, preferably less than 10 Pa, particularly preferably less than 5 Pa.

In one preferred embodiment of the invention, the coating is cured after being applied in step b) by means of UV curing, dual curing, thermal curing, and/or a reaction gas.

In one preferred embodiment of the invention, the proportion of the reaction gas with respect to the total volume of the at least one precursor and reaction gas is greater than 4% by volume, preferably greater than 6% by volume, and less than 20% by volume, preferably less than 10% by volume.

In one preferred embodiment of the invention, the coating is applied at a temperature of the electrical component or of the layer system of −20° C. to 110° C., preferably of −10° C. to 50° C., preferably of 0° C. to 60° C., preferably of 5° C. to 40° C., preferably of 5° C. to 30° C., preferably of 10° C. to 50° C., preferably of 20° C. to 40° C., or preferably of 30° C. to 50° C.

The invention is explained in more detail below with reference to the drawings. The exemplary embodiments relate in particular to an electrical component produced in a roll-to-roll method. In the figures:

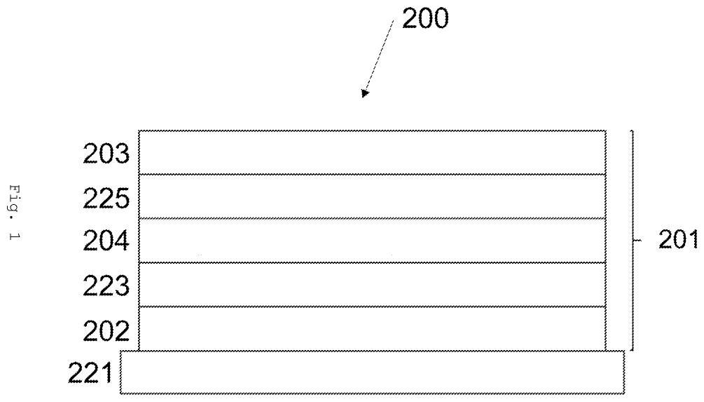

FIG. 1 shows a schematic illustration of one exemplary embodiment of a layer system of an electrical component in cross section;

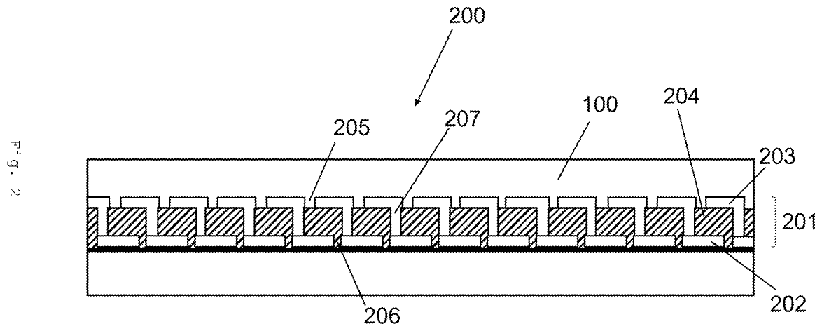

FIG. 2 shows a schematic illustration of one exemplary embodiment of a structured layer system of an electronic component;

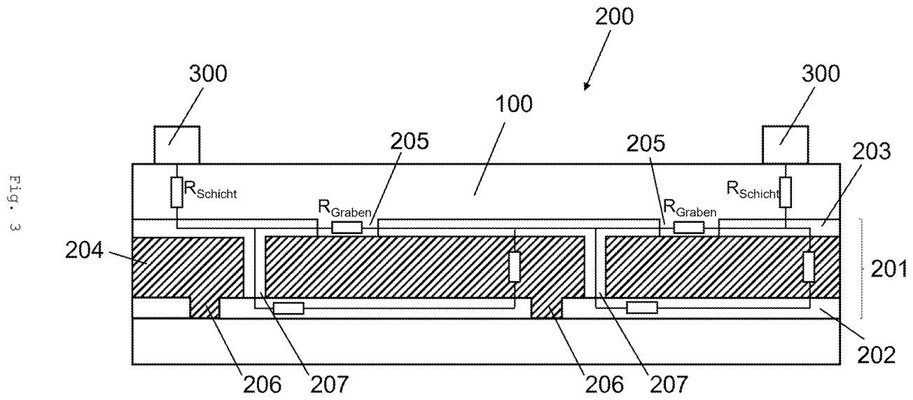

FIG. 3 shows a schematic illustration of one exemplary embodiment of an electrical component having an electrically conductive coating in cross section; and

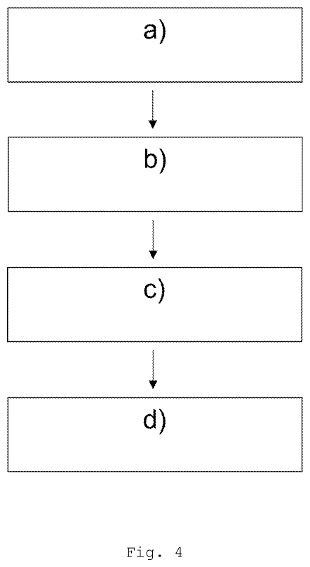

FIG. 4 shows a schematic illustration of one exemplary embodiment of a method for producing an electrically conductive coating of an electrical component in a flowchart.

### EXEMPLARY EMBODIMENTS

FIG. 1 shows a schematic illustration of one exemplary embodiment of a layer system 201 of an electrical component 200 in cross section.

In this exemplary embodiment, the electrical component 200 is a photovoltaic element. The photovoltaic element consists of a sequence of thin layers with the layer system 201, with at least one photoactive layer 204, which are preferably vapor-deposited in vacuo or processed from a solution. The electrical link is implemented via electrodes, e.g. by metal layers, transparent conductive oxides and/or transparent conductive polymers.

The photovoltaic element has a substrate 221, e.g. composed of glass, on which a layer system 201 is situated. The layer system 201 comprises a front electrode 202, e.g. comprising ITO, an n-doped electron transport layer 223, and also a photoactive layer 204. Arranged thereabove there are situated a p-doped hole transport layer 225 and a back electrode 203 composed of aluminum.

In this exemplary embodiment, the photoactive layer 204 is an organic photoactive layer comprising a donor/acceptor system composed of small molecules.

FIG. 2 shows a schematic illustration of one exemplary embodiment of a structured layer system 201 of an electronic component 200.

Identical and functionally equivalent elements have been provided with the same reference signs, and so reference is made to the description above in this respect.

In this exemplary embodiment, the provided substrate 221 is coated and structured with a layer of a front electrode 202, the trenches 206 (P1) being obtained. Afterward, at least the photoactive layer 204 is applied to the front electrode 202. Individual layers can be applied at least in part by a printing process, preferably by an inkjet, screen printing, gravure printing or flexographic printing process, or by means of evaporation of the materials to be applied in vacuo. The at least one photoactive layer 204 is structured, the trenches 207 (P2) being obtained. The layer of the back electrode 203 is applied to the structured photoactive layer 204 and is structured, the trenches 205 (P3) being obtained. In the present exemplary embodiment, the electrical component 200 is a photovoltaic element.

One exemplary embodiment of a structuring of a layer system 201 of an electrical component 200 with the structurings P1, P2, and P3 is illustrated in FIG. 2. The structuring has the following trench structure: a trench 205 of a first type (P3), which interrupts a layer of a front electrode 202, a trench 206 of a second type (P1), which interrupts a layer of a back electrode 203, and a trench 207 of a third type (P2), which interrupts a photoactive layer 204. The trenches 207 of the third type (P2) are filled with an electrically conductive material for electrically contacting the back electrode 203 with the front electrode 202. As a result, the front electrode 202 is electrically conductively led through the photoactive layer 204.

The structuring of the layer system 201, in particular the front electrode 202, the back electrode 203, and the at least one photoactive layer 204, can be effected by means of laser ablation, electron or ion beam ablation, scribing or shadow masks.

The following parameters can be used for the structurings P1/P2/P3 using a laser: P1: 1030 nm wavelength and 50 μm linewidth; P2: 515 nm wavelength and 50 μm linewidth; and P3: 1030 nm wavelength and 100 μm linewidth. In this exemplary embodiment, the width of the trenches 205 of the type P3 is 100 μm and the width of the busbar 300 is 14 mm.

In one exemplary embodiment, the substrate 221 is a film, for example a PET film. The individual layers of the layer system 201 of the photovoltaic element 300 are applied to the substrate 221 and are structured (see FIG. 3). The layers can be applied by means of a PECVD method, for example.

FIG. 3 shows a schematic illustration of one exemplary embodiment of an electrical component 200 having an electrically conductive coating 100 in cross section. Identical and functionally equivalent elements have been provided with the same reference signs, and so reference is made to the description above in this respect.

In this exemplary embodiment, the electrical component 200 is a photovoltaic element. The electrical component 200 has a structured layer system 201.

The electrically conductive coating 100 of an electrical component 200 for electrically conductively contacting a first busbar 300 arranged outside the coating 100 has at least one cell with at least one structured layer system 201, wherein the at least one layer system 201 has a front electrode 202, a back electrode 203, and at least one photoactive layer 204, wherein the at least one photoactive layer 204 is arranged between the front electrode 202 and the back electrode 203. The at least one layer system 201 is structured in such a way that the back electrode 203 is interrupted by at least one trench 205, and at least the back electrode 203 of the at least one cell is coated with the coating 100 and the at least one trench 205 of the back electrode 203 is filled with the coating 100. The coating 100 has a resistivity of 0.01 to 10,000 Ωm, wherein a ratio of the electrical resistance between the back electrode 203 and the first busbar 300 of the coating 100 (R_{layer}) and the electrical resistance over the width of the trench 205 with the coating 100 (R_{trench}) is at least 1:1000.

The electrically conductive coating 100 protects the electrical component 200, in particular the at least one layer system 201 of the electrical component 200, from environmental influences and damage before, during and after final production, and at the same time provides an electrically conductive contacting of the layer system 201, in particular of at least one electrode 202, 203 of the layer system 201, with a busbar 300 arranged outside the coating 100. By virtue of the dimensioning of the P3 trenches (205) in relation to the layer thickness of the coating 100 and the resistivity of the coating 100, the electrical resistance between busbar 300 and back side electrode 203 is small enough for contacting the back side electrode (203), and the electrical resistance between the busbar 300 and the front electrode 202 is large enough to avoid significant losses of a generated electrical current.

In one configuration of the invention, a ratio of the layer thickness of the coating 100 to the width of the at least one trench 205 is at least 1:10, preferably at least 1:30, preferably 1:5 to 1:5000, preferably 1:10 to 1:1000, or preferably 1:20 to 1:200.

In a further configuration of the invention, a width of the at least one trench 205 is 1 μm to 1 mm, preferably 10 μm to 400 μm, and a layer thickness of the coating is 100 nm to 100 μm, preferably 500 nm to 10 μm.

In a further configuration of the invention, a ratio of a layer thickness of the back electrode 203 to a width of the first busbar 300 is at least 1:10, preferably at least 1:30, preferably 1:5 to 1:5000, preferably 1:10 to 1:1000, or preferably 1:20 to 1:200.

In a further configuration of the invention, the width of the first busbar 300 is 0.1 cm to 10 cm, preferably 0.5 cm to 5 cm, or preferably 1 cm to 3 cm.

In a further configuration of the invention, the layer thickness of the back electrode 203 is 10 nm to 1 μm, preferably 20 nm to 500 nm.

In a further configuration of the invention, the coating 100 has a resistivity of 0.1 to 1000 Ωm, preferably of 1 to 500 Ωm, or preferably of 10 to 500 Ωm.

In a further configuration of the invention, the ratio of the electrical resistance between the back electrode 203 and the first busbar 300 of the coating 100 (R_{layer}) and the electrical resistance over the width of the trench 205 with the coating 100 (R_{trench}) is at least 1:5000, preferably at least 1:10,000, preferably 1:1000 to 1:10,0000, or preferably 1:10,000 to 1:10,0000.

In a further configuration of the invention, the at least one layer system 201 is structured in such a way that the structuring has a trench 205 of a first type (P3), which electrically conductively interrupts the back electrode 203, a trench 206 of a second type (P1), which electrically conductively interrupts the front electrode 202, and a trench 207 of a third type (P2), which electrically conductively interrupts the at least one photoactive layer 204, such that the front electrode 202 and the back electrode 203 of the at least one cell are electrically conductively interconnected with one another.

In a further configuration of the invention, the coating 100 is formed on a front side of the electrical component 200 and/or on a back side of the electrical component 200, preferably the coating is formed over the complete extent of the electrical component 200.

In a further configuration of the invention, the coating 100 is formed from:
a) at least one precursor selected from the group consisting of hexamethyldisiloxane (HMDSO), bis-trimethylsilylmethane (BTMSM), tetraethyl orthosilicate (TEOS), hexamethyldisilazane (HMDSN), silane (SiH₄), triethoxysilane (TriEOS), tetramethoxysilane (TMOS), tetramethylsilane (TMS), and trimethoxysilane (TriMOS), bis-diethylamino-silane (BTBAS), preferably using a reaction gas selected from nitrogen or oxygen; or
b) at least one matrix material selected from a), silicon oxycarbides, preferably SiOC or SiOCH, or an SiOCH-like material, preferably silicon carboxynitrides (SiONCH), silicon carbonitrides (SiNCH), silicon nitrides (SiN), silicates (SiO₂), and Al₂O₃; or
c) at least one material selected from b) and at least one dopant, wherein the dopant is selected from the group consisting of diborane, trimethyl boron, and phosphine, or a TCO material, preferably selected from the group consisting of metal alkoxides, metal amides, preferably titanium alkoxide, more particularly preferably titanium tetraisobutoxide, titanium tetraisoethoxide, and titanium tetraisomethoxide, titanium tetra-isopropoxide (TTIP), TiCl₄, dialkyl zinc, preferably dimethyl zinc or diethyl zinc (DEZN), tin chloride, tetramethyltin, tetraethyltin, ITO, In₂O₃, TiO₂, ZnO, and SnO₂.

The electrically conductive coating 100 can be used as a protective layer of an electrical component 200, in particular as winding protection, and for electrically conductively contacting at least one back electrode 203 of a layer system 201 with a first busbar 300 of the electrical component 200.

In a further configuration of the invention, the coating 100 has an elasticity of 80000 psi to 360000 psi, preferably of 10,0000 psi to 300000 psi, preferably of 120000 psi to 260000 psi, or preferably of 10,0000 psi to 200000 psi.

The electrical component 200 having the electrically conductive coating 100 has at least one layer system 201 having a front electrode 202, a back electrode 203, and at least one photoactive layer 204, wherein the at least one photoactive layer 204 is arranged between the front electrode 202 and the back electrode 203, and at least one busbar 300, wherein the coating 100 is arranged between the at least one layer system 201 and the at least one busbar 300, such that at least the back electrode 203 is electrically conductively contacted with the at least one busbar 300. In this exemplary embodiment, the electrical component 200 is a photovoltaic element.

In one configuration of the invention, the electrical component 200 is an organic electrical component 200, preferably an organic photovoltaic element (OPV), an OFET, an OLED or an organic photodetector.

FIG. 4 shows a schematic illustration of one exemplary embodiment of a method for producing an electrically conductive coating 100 of an electrical component 200 in a flowchart. Identical and functionally equivalent elements have been provided with the same reference signs, and so reference is made to the description above in this respect.

The electrically conductive coating 100 of an electronic component 200 can be produced by means of a number of methods. In one exemplary embodiment of the invention, the method for coating the electronic component 200 with the electrically conductive coating 100 comprises the following steps:
a) providing an electrical component 200 having at least one cell with at least one structured layer system 201, having a front electrode 202, a back electrode 203, and at least one photoactive layer 204 arranged between the front electrode 202 and the back electrode 203, wherein the back electrode 203 is interrupted by at least one trench 205;
b) applying at least one precursor, one matrix material and/or one dopant simultaneously or as a mixture by means of a deposition method or a printing method at least onto the back electrode 203 and in the at least one trench 205 of the back electrode 203, such that at least the back electrode 203 is completely covered; and c) obtaining the coating 100.

As a result, the electrical component 200, in particular the layer system 201 of the electrical component 200, is protected from environmental influences and damage during further processing or during use. The method for coating the electronic component 200 with the electrically conductive coating 100 can be used in particular in a roll-to-roll method.

The structured layer system 201 can be obtained for example by laser structuring in each case after applying the individual layers, in particular the layer of the front electrode 202, the at least one photoactive layer 204 and the layer of the back electrode 203.

In a further configuration of the invention, after step c) in a step d) at least one first busbar 300 is applied to the coating 100.

In a further configuration of the invention, the method is carried out in a roll-to-roll method, preferably a continuous roll-to-roll method.

In one exemplary embodiment, the electrically conductive coating 100 is applied completely to the back electrode 203 or to the entire electrical component 200. For this purpose, by means of a PECVD method, the precursor hexamethyldisiloxane (HMDSO) with a gas volumetric flow rate of 150 sccm, the precursor tetra-isopropyl-titanium (TTIP) with a gas volumetric flow rate of 1-15 sccm, and oxygen with a gas volumetric flow rate of 2000 sccm are applied to the electrical component 200. Argon is used as carrier gas. The materials are deposited until an 800 nm thick layer is present as a mixed layer. The electrical component 200 is temperature-regulated to 5° C. during the deposition of the materials. In order to form the coating 100, radical/-ionized species (e.g. O₂+, O, Si₂O(CH₃)₅) are generated in-situ by plasma excitation. In the PECVD method, the electrical plasma power is 10.5 kW and the working pressure is 5 Pa.

In a further exemplary embodiment, the coating 100 is obtained in a PVD method using two materials by application by means of evaporation of an insulator and a TCO matrix material (ZnO, TiO₂, SnO₂). In this case, an insulating material, e.g. SiO₂, is co-evaporated with a TCO matrix material, e.g. TiO₂, onto the electrical component 200.

In a further exemplary embodiment, the coating 100 is obtained in an ALD method with an insulator and a TCO matrix material (ZnO, TiO₂, SnO₂).

1. An electrically conductive coating (100) of an electrical component (200) for electrically conductively contacting a first busbar (300) arranged outside the coating (100), the electrical component (200) having at least one cell with at least one structured layer system (201), wherein the at least one layer system (201) has a front electrode (202), a back electrode (203), and at least one photoactive layer (204), and the at least one photoactive layer (204) is arranged between the front electrode (202) and the back electrode (203), wherein the at least one layer system (201) is structured in such a way that the back electrode (203) is interrupted by at least one trench (205), and at least the back electrode (203) of the at least one cell is coated with the coating (100) and the at least one trench (205) of the back electrode (203) is filled with the coating (100), characterized in that the coating (100) has a resistivity of 0.01 to 10,000 Ωm, wherein a ratio of the electrical resistance between the back electrode (203) and the first busbar (300) of the coating (100) (R_{layer}) and the electrical resistance over the width of the trench (205) with the coating (100) (R_{trench}) is at least 1:1000.

2. The electrically conductive coating (100) as claimed in claim 1, wherein a ratio of the layer thickness of the coating (100) to the width of the at least one trench (205) is at least 1:10, preferably 1:10 to 1:1000, and/or a width of the at least one trench (205) is 1 μm to 1 mm, and a layer thickness of the coating (100) is 100 nm to 100 μm.

3. The electrically conductive coating (100) as claimed in claim 1 or 2, wherein a ratio of a layer thickness of the back electrode (203) to a width of the first busbar (300) is at least 1:10, preferably 1:10 to 1:1000, and/or the width of the first busbar (300) is 0.1 cm to 10 cm, and the layer thickness of the back electrode (203) is 10 nm to 1 μm.

4. The electrically conductive coating (100) as claimed in any of the preceding claims, wherein the coating (100) has a resistivity of 0.1 to 1000 Ωm, and/or the ratio of the electrical resistance between the back electrode (203) and the first busbar (300) of the coating (100) (R_{layer}) and the electrical resistance over the width of the trench (205) with the coating (100) (R_{trench}) is at least 1:5000.

5. The electrically conductive coating (100) as claimed in any of the preceding claims, wherein the at least one layer system (201) is structured in such a way that the structuring has a trench (205) of a first type (P3), which electrically conductively interrupts the back electrode (203), a trench (206) of a second type (P1), which electrically conductively interrupts the front electrode (202), and a trench (207) of a third type (P2), which electrically conductively interrupts the at least one photoactive layer (204), such that the front electrode (202) and the back electrode (203) of the at least one cell are electrically conductively interconnected with one another.

6. The electrically conductive coating (100) as claimed in any of the preceding claims, wherein the coating (100) is formed on a front side of the electrical component (200) and/or on a back side of the electrical component (200), preferably the coating (100) is formed over the complete extent of the electrical component (200).

7. The electrically conductive coating (100) as claimed in any of the preceding claims, wherein the coating (100) is formed from:
a) at least one precursor selected from the group consisting of hexamethyldisiloxane (HMDSO), bis-trimethylsilylmethane (BTMSM), tetraethyl orthosilicate (TEOS), hexamethyldisilazane (HMDSN), silane (SiH₄), triethoxysilane (TriEOS), tetramethoxysilane (TMOS), tetramethylsilane (TMS), and trimethoxysilane (TriMOS), bis-diethylamino-silane (BTBAS), preferably using a reaction gas selected from nitrogen or oxygen; or
b) at least one matrix material selected from a), silicon oxycarbides, preferably SiOC or SiOCH, or an SiOCH-like material, preferably silicon carboxynitrides (SiONCH), silicon carbonitrides (SiNCH), silicon nitrides (SiN), silicates (SiO₂), and Al₂O₃; or
c) at least one material selected from b) and at least one dopant, wherein the dopant is selected from the group consisting of diborane, trimethyl boron, and phosphine, or a TCO material, preferably selected from the group consisting of metal alkoxides, metal amides, preferably titanium alkoxide, more preferably titanium tetraisobutoxide, titanium tetraisoethoxide, and titanium tetraisomethoxide, titanium tetra-isopropoxide (TTIP), TiCl₄, dialkyl zinc, preferably dimethyl zinc or diethyl zinc (DEZN), tin chloride, tetramethyltin, tetraethyltin, ITO, In₂O₃, TiO₂, ZnO, and SnO₂.

8. A use of the electrically conductive coating (100) as claimed in any of claims 1 to 7 as a protective layer of an electrical component (200), in particular as winding protection, and for electrically conductively contacting at least one back electrode (203) of a layer system (201) with a first busbar (300) of the electrical component (200), wherein the coating (100) preferably has an elasticity of 80,000 psi to 360,000 psi.

9. An electrical component (200), preferably a flexible electrical component (200), having an electrically conductive coating (100) as claimed in any of claims 1 to 7, and at least one layer system (201) having a front electrode (202), a back electrode (203), and at least one photoactive layer (204), wherein the at least one photoactive layer (204) is arranged between the front electrode (202) and the back electrode (203), and at least one busbar (300), wherein the coating (100) is arranged between the at least one layer system (201) and the at least one busbar (300), such that at least the back electrode (203) is electrically conductively contacted with the at least one busbar (300), wherein the electrical component (200) is preferably a photovoltaic element.

10. A method for coating an electrical component (200) with an electrically conductive coating (100) as claimed in any of claims 1 to 7, preferably in a roll-to-roll method, comprising the following steps:
a) providing an electrical component (200) having at least one cell with at least one structured layer system (201), having a front electrode (202), a back electrode (203), and at least one photoactive layer (204) arranged between the front electrode (202) and the back electrode (203), wherein the back electrode (203) is interrupted by at least one trench (205);
b) applying at least one precursor, one matrix material and/or one dopant simultaneously or as a mixture by means of a deposition method or a printing method at least onto the back electrode (203) and in the at least one trench (205) of the back electrode (203), such that at least the back electrode (203) is completely covered; and
c) obtaining the coating (100).
